(19) United States
(12) Patent Application Publication
(10) Pub. No.: US 2017/0098619 A1
(43) Pub. Date: Apr. 6, 2017

(54) SEMICONDUCTOR CHIP, SEMICONDUCTOR PACKAGE INCLUDING THE SAME, AND METHOD OF FABRICATING THE SAME

(71) Applicant: Samsung Electronics Co., Ltd., Suwon-si (KR)

(72) Inventors: Jung-Hoon Han, Hwasepmg-si (KR); Kyehee Yeom, Suwon-si (KR)

(73) Assignee: Samsung Electronics Co., Ltd., Suwon-si (KR)

(21) Appl. No.: 15/284,921

(22) Filed: Oct. 4, 2016

(30) Foreign Application Priority Data
Oct. 5, 2015 (KR) 10-2015-0139733

(51) Int. Cl. H01L 23/00; H01L 25/00; H01L 21/56; H01L 25/065; H01L 23/31; H01L 21/48

(52) U.S. Cl. CPC H01L 24/02; H01L 24/05; H01L 24/48; H01L 23/3114; H01L 21/4853; H01L 21/565; H01L 25/0657; H01L 25/50; H01L 2224/05008; H01L 2224/05025; H01L 2224/02373; H01L 2224/02381; H01L 2224/024; H01L 2924/06; H01L 2224/0239; H01L 2924/01013; H01L 2224/0218; H01L 2224/0219; H01L 2924/01022; H01L 2924/04941; H01L 2224/04042; H01L 2224/48157; H01L 2225/0651; H01L 2225/06555; H01L 2225/06582

(57) ABSTRACT

A semiconductor chip, a semiconductor package including the same, and a method of fabricating the same are provided. The semiconductor chip includes an integrated circuit on a substrate, a pad electrically connected to the integrated circuit, a lower insulating structure having a contact hole exposing the pad, and a conductive pattern including a contact portion filling the contact hole, a conductive line portion provided on the lower insulating structure to extend in a specific direction, and a bonding pad portion. The contact portion has a first thickness in a direction substantially perpendicular to a top surface of the substrate and a second thickness in another direction substantially parallel to the top surface of the substrate, the first thickness is greater than the second thickness, and the lower insulating structure includes a plurality of air gaps formed therein.

### CROSS-REFERENCE TO RELATED APPLICATIONS

This U.S. non-provisional patent application claims priority under 35 U.S.C. §119 to Korean Patent Application No. 10-2015-0139733, filed on Oct. 5, 2015, in the Korean Intellectual Property Office, the entire contents of which are hereby incorporated by reference.

### BACKGROUND OF THE INVENTION

Some example embodiments relate to a semiconductor chip with a redistribution layer, a semiconductor package including the same, and/or a method of fabricating the same.

Due to their small-size, multifunctionality, and/or low-cost characteristics, semiconductor devices are relevant elements in the electronic industry. Generally, semiconductor devices are classified into a memory device for storing data, a logic device for processing data, and a hybrid device for performing various functions.

As the electronic industry advances, there is an increasing demand for a semiconductor device with a higher integration density and higher performance. To meet such a demand, it is necessary to reduce a process margin (for example, in a photolithography process). Although a variety of studies are being conducted to solve the difficulties, the reduction of the process margin may lead to challenges in fabricating a semiconductor device.

Various package technologies have been developed to meet demands for large capacity, thin, and small size of semiconductor devices and/or electronic appliances. For example, a package technology of vertically stacking semiconductor chips has been used to allow an electronic product to have high density and large capacity. The use of this package technology may allow many kinds of semiconductor chips to be integrated on a reduced area, when compared to typical packages having a single semiconductor chip.

### SUMMARY

Some example embodiments of the inventive concepts provide a semiconductor chip with a redistribution layer formed using a deposition and patterning process.

Some example embodiments of the inventive concepts provide a method of fabricating a semiconductor chip with a redistribution layer, using a deposition and patterning process.

Some example embodiments of the inventive concepts provide a semiconductor package, in which a semiconductor chip with a redistribution layer is provided.

According to some example embodiments of the inventive concepts, a semiconductor chip may include an integrated circuit on a substrate, a pad electrically connected to the integrated circuit, a lower insulating structure having a contact hole exposing the pad, and a conductive pattern including a contact portion filling the contact hole, a conductive line portion provided on the lower insulating structure to extend in a specific direction, and a bonding pad portion. The contact portion may have a first thickness in a direction substantially perpendicular to a top surface of the substrate and a second thickness in another direction substantially parallel to the top surface of the substrate, the first thickness may be greater than the second thickness, and the lower insulating structure may include a plurality of air gaps formed therein.

In some example embodiments, the lower insulating structure may include a plurality of lower insulating layers stacked, for example sequentially stacked, on the substrate.

In some example embodiments, the air gaps may be provided in the uppermost layer of the lower insulating layers.

In some example embodiments, the lower insulating structure may include a first lower insulating layer and a second lower insulating layer stacked, for example sequentially stacked on the substrate, the first lower insulating layer and the second lower insulating layer may include inorganic materials that are different from each other, and the air gaps may be interposed between the first and second lower insulating layers.

In some example embodiments, when viewed in a plan view, the air gaps may not overlap the bonding pad portion.

In some example embodiments, the lower insulating structure may be provided to have a recess region formed in an upper portion thereof, and when viewed in a plan view, the recess region may not be overlapped with the conductive pattern.

In some example embodiments, the recess region may have a sidewall aligned with the sidewall of the conductive pattern, and the recess region may have a bottom surface lower than a top surface of the lower insulating structure provided below the conductive pattern.

In some example embodiments, the contact portion may be provided to fill the contact hole and define a dent.

In some example embodiments, the pad may be electrically connected to the integrated circuit thereunder through a plurality of metal layers and a plurality of vias.

In some example embodiments, when viewed in a plan view, the pad may be provided on a center area of the semiconductor chip and the bonding pad portion may be provided on a peripheral area of the semiconductor chip.

In some example embodiments, the semiconductor chip may further include an upper insulating structure having a first opening exposing the bonding pad portion. The upper insulating structure may include an upper insulating layer covering the lower insulating structure and the conductive pattern, and a polymer layer on the upper insulating layer.

In some example embodiments, the upper insulating layer may be provided to directly cover top and side surfaces of the conductive pattern.

In some example embodiments, the upper insulating layer may include a silicon nitride layer, a silicon oxide layer, or a silicon oxynitride layer.

In some example embodiments, the polymer layer may include polyimide, fluoro carbon, resin, or synthetic rubber.

In some example embodiments, the upper insulating structure may further include a second opening exposing the contact portion.

In some example embodiments, each or at least one of the lower insulating layers may include a silicon nitride layer, a silicon oxide layer, or a silicon oxynitride layer.

In some example embodiments, the conductive pattern may include an aluminum-containing material.

In some example embodiments, a width of the contact hole may be smaller than the width of the first opening, when measured in the specific direction.

According to some example embodiments of the inventive concepts, a semiconductor chip may include an integrated circuit on a substrate, a pad electrically connected to the integrated circuit, a lower insulating structure having a contact hole exposing the pad, and a conductive pattern including a contact portion filling the contact hole, a conductive line portion provided on the lower insulating structure to extend in a specific direction, and a bonding pad portion. The lower insulating structure may include a first region and a second region, the top surface thereof may be lower than the top surface of the first region, the first region may overlap the conductive pattern a plan view, the second region may be exposed by the conductive pattern, and the lower insulating structure a include a plurality of air gaps provided therein.

In some example embodiments, the semiconductor chip may further include an upper insulating structure having an opening exposing the bonding pad portion. The upper insulating structure may include an upper insulating layer covering the lower insulating structure and the conductive pattern, and a polymer layer on the upper insulating layer.

In some example embodiments, the upper insulating layer may be provided to directly cover a top surface of the second region.

In some example embodiments, the semiconductor chip may further include a barrier pattern interposed between the lower insulating structure and the conductive pattern. The conductive pattern may include an aluminum-containing material, and the barrier pattern may include Ti, TiN, or any combination thereof.

According to some example embodiments of the inventive concepts, a semiconductor package may include a package substrate, and a semiconductor chip provided on and electrically connected to the package substrate with a wire. The semiconductor chip may include first and second surfaces facing each other, the first surface facing the package substrate, a pad provided on the second surface, a lower insulating structure having a contact hole exposing the pad, a conductive pattern including a contact portion filling the contact hole, a conductive line portion provided on the lower insulating structure to extend in a specific direction, and a bonding pad portion in contact with the wire, and an upper insulating structure having an opening exposing the bonding pad portion. The lower insulating structure may be provided to have a recess region formed in an upper portion thereof, when viewed in a plan view, the recess region may not overlap the conductive pattern, and the lower insulating structure may include a plurality of air gaps formed therein.

In some example embodiments, the upper insulating structure may include an inorganic insulating layer covering the lower insulating structure and the conductive pattern and including a silicon-containing material, and a polymer layer on the inorganic insulating layer.

In some example embodiments, the inorganic insulating layer may be provided to directly cover side and bottom surfaces of the recess region.

In some example embodiments, the semiconductor chip further may include an integrated circuit electrically connected to the pad, and the integrated circuit may be electrically connected to the package substrate through the pad, the conductive pattern, and the wire.

In some example embodiments, the semiconductor chip may include a plurality of semiconductor chips, which are stacked, for example sequentially stacked on the package substrate, and each of which is electrically connected to the package substrate through the bonding pad portion and the

In some example embodiments, the lower insulating structure ay include a first lower insulating layer adjacent to the pad, a second lower insulating layer adjacent to the conductive pattern, and a third lower insulating layer interposed between the first and second lower insulating layers, and the air gaps may be provided in the second lower insulating layer.

According to some example embodiments of the inventive concepts, a method of fabricating a semiconductor chip may include forming a pad on a substrate, the pad being electrically connected to an integrated circuit, forming a lower insulating structure on the substrate to cover the pad, the lower insulating structure including a plurality of air gaps formed therein, patterning the lower insulating structure to form a contact hole exposing the pad, forming a conductive layer on the lower insulating structure to fill the contact hole, the conductive layer being formed using a physical vapor deposition process, and patterning the conductive layer to form a conductive pattern extending in a specific direction on the lower insulating structure. The conductive layer in the contact hole may have a first thickness in a direction substantially perpendicular to a top surface of the substrate and a second thickness in a direction substantially parallel to the top surface of the substrate, and the first thickness may be greater than the second thickness.

In some example embodiments, the forming of the lower insulating structure may include forming at least one lower insulating layer on the substrate, patterning the lower insulating layer to form a plurality of lower insulating patterns, the lower insulating patterns defining empty spaces therebetween, and forming an additional insulating layer on the lower insulating patterns to form air gaps from the empty spaces.

In some example embodiments, the conductive pattern may include a bonding pad portion, the method further may include forming an upper insulating structure on the conductive pattern, the upper insulating structure including an upper insulating layer covering the conductive pattern and a polymer layer on the upper insulating layer, and pattering the upper insulating structure to form an opening exposing the bonding pad portion.

In some example embodiments, the patterning of the conductive layer may include forming a recess region in an upper portion of the lower insulating structure, and when viewed in a plan view, the recess region may be formed to be not overlapped with the conductive pattern.

In some example embodiments, the conductive layer may include an aluminum-containing material, and the pattering of the conductive layer may include forming a photoresist pattern on the conductive layer, and performing a dry etching process on the conductive layer using the photoresist pattern as an etch mask.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a sectional view illustrating a semiconductor package according to some example embodiments of the inventive concepts.

FIG. 2 is a plan view schematically illustrating a second surface of a first semiconductor chip according to some example embodiments of the inventive concepts.

FIG. 3 is a sectional view of sections, which are respectively taken along lines I-I′ and II-II′ of FIG. 2, and illustrates a first semiconductor chip according to some example embodiments of the inventive concepts.

FIG. 4A is an enlarged sectional view of a region M of FIG. 3.

FIG. 4B is an enlarged sectional view of a region N of FIG. 3.

FIGS. 5 through 11 are sectional views taken along lines I-I′ and II-II′ of FIG. 2 to illustrate a method of fabricating a first semiconductor chip, according to some example embodiments of the inventive concepts.

FIG. 10 is a sectional view of sections, which are respectively taken along lines I-I′ and II-II′ of FIG. 2, and illustrates a first semiconductor chip according to some example embodiments of the inventive concepts.

FIG. 11 is a sectional view of sections, which are respectively taken along lines I-I′ and II-II′ of FIG. 2, and illustrates a first semiconductor chip according to some example embodiments of the inventive concepts.

FIG. 12 is a sectional view of sections, which are respectively taken along lines I-I′ and II-II′ of FIG. 2, and illustrates a first semiconductor chip according to some example embodiments of the inventive concepts.

FIG. 13 is a sectional view of sections, which are respectively taken along lines I-I′ and II-II′ of FIG. 2, and illustrates a first semiconductor chip according to some example embodiments of the inventive concepts.

FIG. 14 is a sectional view of sections, which are respectively taken along lines I-I′ and II-II′ of FIG. 2, and illustrates a first semiconductor chip according to some example embodiments of the inventive concepts.

FIG. 15 is a sectional view illustrating a semiconductor package according to some example embodiments of the inventive concepts.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by some example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

The inventive concepts will now be described more fully hereinafter with reference to the accompanying drawings, in which example embodiments of the inventive concepts are shown. The inventive concepts and methods of achieving them will be apparent from the following example embodiments that will be described in more detail with reference to the accompanying drawings. The example embodiments of the inventive concepts may, however, be embodied in different forms and should not be constructed as limited to the embodiments set forth herein. Rather, these example embodiments are provided so that this disclosure will be thorough and complete, and will fully convey the scope of the inventive concepts to those skilled in the art.

As used herein, the singular terms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Similarly, it will be understood that when an element such as a layer, region or substrate is referred to as being “on,” “connected to” or “coupled to” another element, it can be directly on, directly connected to or directly coupled to the other element, or intervening elements may be present. In contrast, the term “directly” means that there are no intervening elements. Additionally, the embodiment in the detailed description will be described with sectional views as ideal example views of the inventive concepts. Accordingly, shapes of the example views may be modified according to manufacturing techniques and/or allowable errors. Therefore, the embodiments of the inventive concepts are not limited to the specific shape illustrated in the example views, but may include other shapes that may be created according to manufacturing processes. As used herein the term “and/or” includes any and all combinations of one or more of the associated listed items. Further, it will be understood that when a layer is referred to as being “under” another layer_{;} it can be directly under or one or more intervening layers may also be present. In addition, it will also be understood that a layer is referred to as being “between” two layers, it can be the only layer between the two layers, or one or more intervening layers may also be present.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of some example embodiments.

In the drawing figures, the dimensions of layers and regions may be exaggerated for clarity of illustration. Like reference numerals refer to like elements throughout. The same reference numbers indicate the same components throughout the specification.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

Some example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein. As used herein, expressions such as “at least one of,” when preceding a list of elements, modify the entire list of elements and do not modify the individual elements of the list.

When the terms “about” or “substantially” are used in this specification in connection with a numerical value, it is intended that the associated numerical value include a tolerance of ±10% around the stated numerical value. Moreover, when reference is made to percentages in this specification, it is intended that those percentages are based on weight, i.e., weight percentages. The expression “up to” includes amounts of zero to the expressed upper limit and all values therebetween. When ranges are specified, the range includes all values therebetween such as increments of 0.1%. Moreover, when the words “generally” and “substantially” are used in connection with geometric shapes, it is intended that precision of the geometric shape is not required but that latitude for the shape is within the scope of the disclosure. Although the tubular elements of the embodiments may be cylindrical, other tubular cross-sectional forms are contemplated, such as square, rectangular, oval, triangular and others.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would he illustrated by a plan view of the electronic device. The plurality of device structures may be arranged in an array and/or in a two-dimensional pattern.

Example embodiments of the inventive concepts explained and illustrated herein include their complementary counterparts. The same reference numerals or the same reference designators denote the same elements throughout the specification.

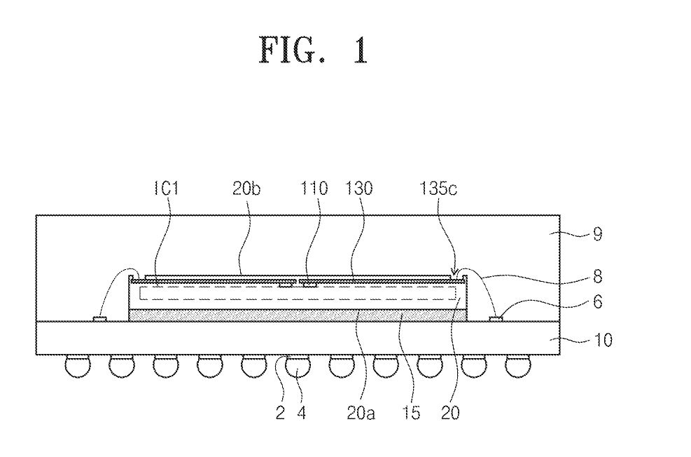

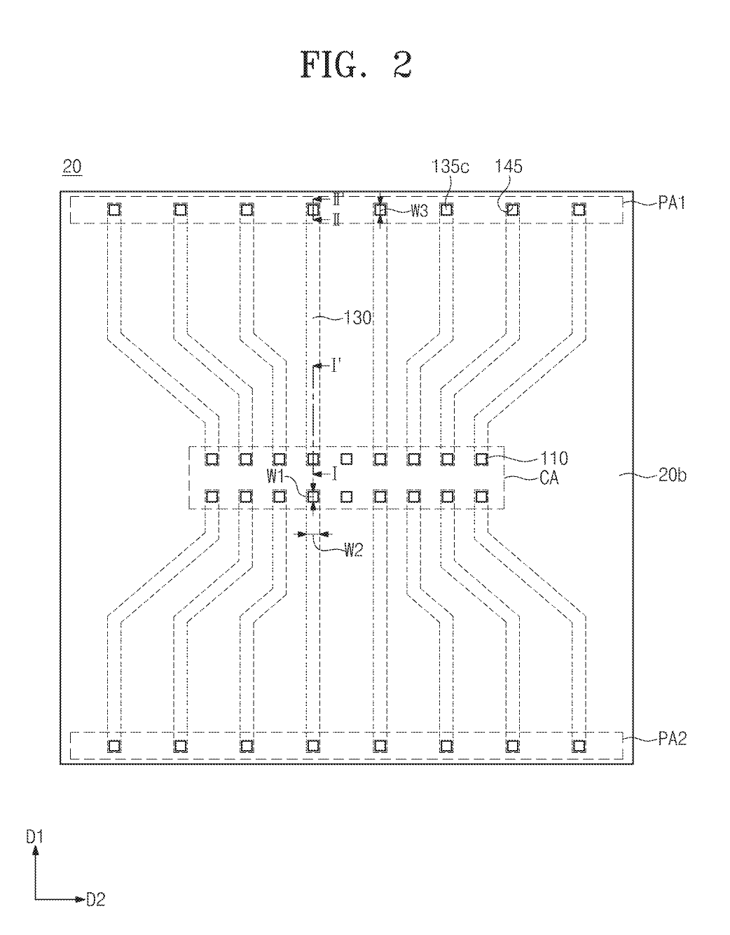

FIG. 1 is a sectional view illustrating a semiconductor package according to some example embodiments of the inventive concepts. FIG. 2 is a plan view schematically illustrating a second surface of a first semiconductor chip according to some example embodiments of the inventive concepts.

Referring to FIGS. 1 and 2, a first semiconductor chip 20 may be mounted on a package substrate 10. As an example, the package substrate 10 may be a printed circuit board (PCB). The package substrate 10 may include circuit patterns (not shown) provided on one or both of top and bottom surfaces thereof. At least one of the circuit patterns may be electrically connected to first outer pads 2, which may be provided on the bottom surface of the package substrate 10. Outer terminals 4 (e.g., solder bumps or solder balls) may be respectively attached on the first outer pads 2 to electrically connect the package substrate 10 to an external device. At least one other of the circuit patterns may he electrically connected to second outer pads 6, which may be provided on the top surface of the package substrate 10.

The first semiconductor chip 20 may have a first surface 20a facing the package substrate 10 and a second surface 20b facing the first surface 20a. The first semiconductor chip 20 may include a center area CA and first and second peripheral areas PA1 and PA2. The center area CA may be positioned at a region including a center of the second surface 20b of the first semiconductor chip 20. The first and second peripheral areas PA1 and PA2 may be positioned adjacent to opposite sidewalls, respectively, of the first semiconductor chip 20. The center area CA may be disposed between the first and second peripheral a as PA1 and PA2.

The first semiconductor chip 20 may include a first integrated circuit IC1, pads 110, and redistribution layers 130. The first integrated circuit IC1 may be provided in a portion of the first semiconductor chip 20 positioned adjacent to the second surface 20b. The pads 110 may be electrically connected to the first integrated circuit IC1. When viewed in a plan view, the pads 110 may be disposed on the center area CA.

The redistribution layers 130 may be disposed on the pads 110. The redistribution layers 130 may include bonding pad portions 135c. The bonding pad portions 135c may be electrically connected to the first integrated circuit IC1 via the pads 110. The bonding pad portions 135c may be provided on the first and second peripheral areas PA1 and PA2. The bonding pad portions 135c may be exposed to the outside. The redistribution layers 130 may be configured to allow signals from the first and second peripheral areas PA1 and PA2 to be applied to the pads 110 of the center area CA through the bonding pad portions 135c.

The inventive concepts are not limited to the illustrated example of the pads 110 and the redistribution layers 130, and example embodiments of the inventive concepts may be variously changed in consideration of a type or use of a semiconductor package.

The first semiconductor chip 20 may be one of a number of various types of memory chips (e.g., DRAM chips or FLASH memory chips). The first integrated circuit IC1 may include memory cells for storing data and a control and/or power circuit for controlling operations of the memory cells.

The first semiconductor chip 20 may be attached to the package substrate 10 using a first adhesive layer 15. The first adhesive layer 15 may be an insulating layer or tape (e.g., containing an epoxy or silicone-based material).

Wires 8 may be provided to electrically connect the bonding pad portions 135c of the first semiconductor chip 20 to the second outer pads 6 of the package substrate 10, respectively. The first semiconductor chip 20 may communicate with an external controller (not shown) through the wires 8. The wires 8 may be used to transmit various data, such as control signals containing address and command data, voltage signals, and any other data, to the first semiconductor chip 20 from the controller. Also, the wires 8 may be used to transmit data, which are read out from the memory cells of the first semiconductor chip 20, to the controller.

A mold layer 9 may be provided on the package substrate 10 to cover the first semiconductor chip 20 and the wires 8. The mold layer 9 may be configured to protect the first semiconductor chip 20 and the wires 8 against external environment. The mold layer 9 may include an epoxy molding compound material.

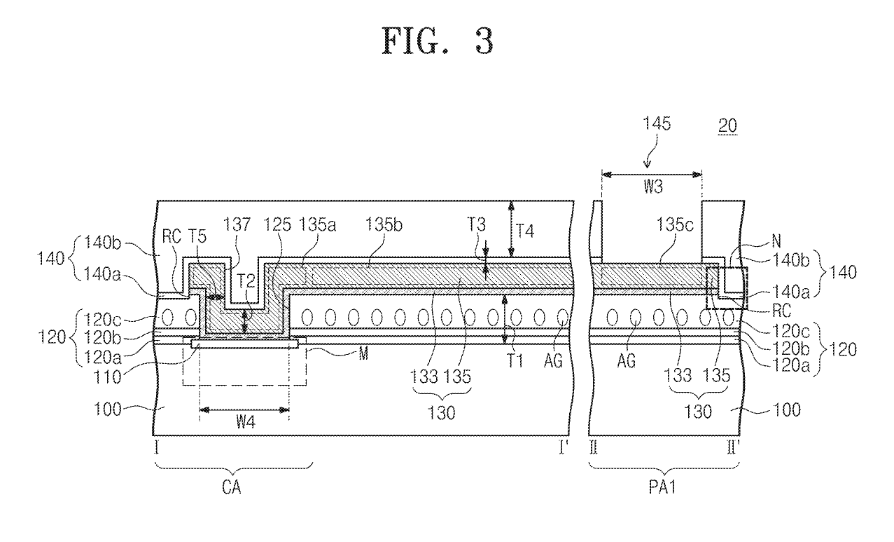

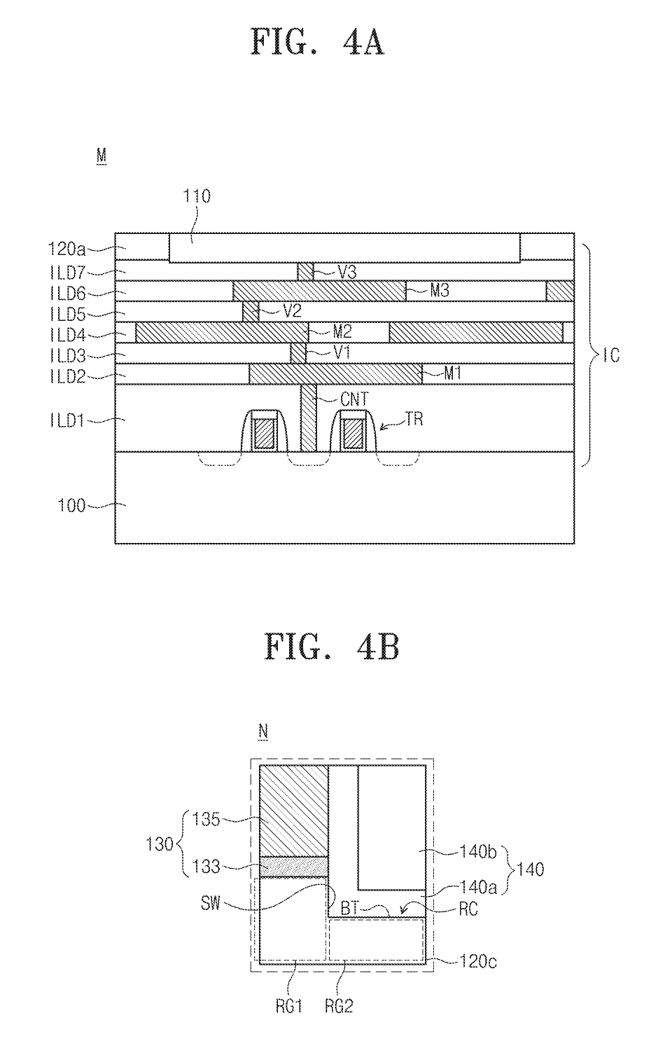

FIG. 3 is a sectional view of various sections, which are respectively taken along lines I-I′ and II-II′ of FIG. 2, and illustrates a first semiconductor chip according to some example embodiments of the inventive concepts. FIG. 4A is an enlarged sectional view of a region M of FIG. 3. FIG. 4B is an enlarged sectional view of a region N of FIG. 3. In the following description, the first semiconductor chip 20 will be described in more detail, without repeating an overlapping description of the semiconductor package previously described with reference to FIGS. 1 and 2.

Referring to FIGS. 2, 3, 4A, and 4B, the pads 110 may be provided on a center area CA of a semiconductor substrate 100. The semiconductor substrate 100 may be a silicon wafer, a germanium wafer, or a silicon-germanium wafer. The pads 110 may be arranged to form two columns within the center area CA, but the inventive concepts may not be limited thereto. The pads 110 may be formed of or include a conductive material (e.g., aluminum (Al)). At least one of the pads 110 may have a first width W1, when measured in a first direction D1 substantially parallel to a top surface of the semiconductor substrate 100. In some example embodiments, the first width W1 may range from about 5 μm to about 50 μm. Hereinafter, one of the pads 110 will be described as an example, for concise description.

The pad 110 may be electrically connected to the first integrated circuit IC1 in the first semiconductor chip 20. Referring back to FIG. 4A, the first integrated circuit IC1 may be disposed on the semiconductor substrate 100. The first integrated circuit IC1 may include a plurality of transistors TR, a plurality of metal layers M1-M3, and a plurality of vias V1-V3.

Each of the transistors TR may include a gate electrode and impurity regions provided at both side of the gate electrode. The impurity regions may be doped regions, which may be formed by injecting impurities into the semiconductor substrate 100. Each of the transistors TR may be used as a part of the memory cells or as a part of the control and/or power circuit for controlling operations of the memory cells.

First to seventh interlayered insulating layers ILD1-ILD7 may be stacked, for example sequentially stacked on the semiconductor substrate 100. The first interlayered insulating layer ILD1 may be provided to cover the transistors TR. A contact CNT may be provided to pass through the first interlayered insulating layer ILD1 and may be connected to one of the impurity regions of the transistors TR.

A first metal layer M1, a second metal layer M2, and a third metal layer M3 may be provided in the second interlayered insulating layer ILD2, the fourth interlayered insulating layer ILD4, and the sixth interlayered insulating layer ILD6, respectively. The pad 110 may be provided on the seventh interlayered insulating layer ILD7. A first via V1 may be provided between the first and second metal layers M1 and M2, a second via V2 may be provided between the second and third metal layers M2 and M3, and a third via V3 may be provided between the third metal layer M3 and the pad 110. The pad 110 may be electrically connected to the transistors TR through the metal layers M1-M3 and the vias V1-V3.

Referring back to FIGS. 2 and 3, a lower insulating structure 120 may be disposed on a top surface of the semiconductor substrate 100, The lower insulating structure 120 may be disposed to at least partially cover the pad 110. The lower insulating structure 120 may have a first thickness T1. As an example, the first thickness T1 may range from about 0.1 μm to about 3 μm.

A contact hole 125 may be provided to penetrate the lower insulating structure 120 and expose the remaining portion of the pad 110. The contact hole 125 may have a fourth width W4, when measured in the first direction D1. The fourth width W4 may be smaller than the first width W1. For example, the fourth width W4 may range from about 5 μm to about 50 μm.

The lower insulating structure 120 may include first to third lower insulating layers 120a, 120b, and 120c, which are stacked, for example sequentially stacked on the semiconductor substrate 100. For example, the second lower insulating layer 120b may be interposed between the first and third lower insulating layers 120a and 120c. Here, the third lower insulating layer 120c may have a thickness greater than the thickness of the first lower insulating layer 120a and/or the thickness of the second lower insulating layer 120b.

Each of the first to third lower insulating layers 120a, 120h, and 120c may be formed of or include an inorganic insulating layer (e.g., of silicon nitride, silicon oxide, or silicon oxynitride). As an example, each of the first and third lower insulating layers 120a and 120c may include a silicon oxide layer, and the second lower insulating layer 120b may include a silicon nitride layer. Here, the first semiconductor chip 20 may be a DRAM chip.

The lower insulating structure 120 may have a top portion provided with a recess region RC. For example, the third lower insulating layer 120c may be provided to define the recess region RC. When viewed in a plan view, the recess region RC may be spaced apart from the redistribution layer 130. In other words, the recess region RC may not overlap the redistribution layer 130, when viewed in a plan view.

Referring back to FIG. 413 the recess region RC may have a bottom surface BT, which is positioned at a lower level than the top surface of the third lower insulating layer 120c provided under the redistribution layer 130. An upper insulating layer 140a may be provided to directly cover a sidewall SW and the bottom surface BT of the recess region RC.

For example, the lower insulating structure 120 may include a first region RGI and a second region RG2. When viewed in a plan view, the first region RG1 may overlap the redistribution layer 130, and the second region RG2 may overlap the recess region RC. Here, a top surface of the first region RG1 may be higher than a top surface of the second region RG2 (e.g., the bottom surface BT of the recess region RC).

The lower insulating structure 120 may include a plurality of air gaps AG therein. As an example, the air gaps AG may be formed in the third lower insulating layer 120c. Although not shown, when viewed in a plan view, each of the air gaps AG may be shaped like a circle, rectangle, or square. The air gaps AG may be arranged in the first and second directions D1 and D2. Here, the second direction D2 may be selected to cross the first direction D1 and be substantially parallel to the top surface of the semiconductor substrate 100. Alternatively, each of the air gaps AG may be a line-shaped structure extending in the second direction D2, but the inventive concepts may not be limited thereto.

Even if, in order to realize an electric isolation of the redistribution layer 130, the thickness T1 of the lower insulating structure 120 becomes sufficiently large, the presence of the air gaps AG may make it possible to reduce an effective dielectric constant of the lower insulating structure 120. Accordingly, it is possible to substantially prevent the redistribution layer 130 from being capacitively coupled with the metal layers M1-M3.

The redistribution layer 130 may be provided on the lower insulating structure 120 to fill at least a portion of the contact hole 125 and be electrically connected to the pad 110. In some example embodiments, as shown in FIG. 2, a plurality of redistribution layers 130 may be provided on the lower insulating structure 120. When viewed in a plan view, each of, or at least one of, the redistribution layers 130 may be a line-shaped structure extending from the pads 110 toward the first direction D1. Some of the redistribution layers 130 may extend in a direction opposite to the first direction D1. For example, the redistribution layers 130 may extend from the center area CA to the first peripheral area PA1 or from the center area CA to the second peripheral area PA2. At least one of the redistribution layers 130 may include a portion extending in a direction crossing the first direction D1. Accordingly, the redistribution layers 130 may be disposed to have end portions that are uniformly arranged on the first and second peripheral areas PA1 and PA2.

At least one of the redistribution layers 130 may have a second width W2, when measured in the second direction D2. As an example, each of the redistribution layers 130 may serve as a signal line, a power line, or a ground line. In some example embodiments, a width of each of, or at least one of, the redistribution layers 130 may be dependent on its assigned function. For example, the second width W2 may range from about 2 μm to about 200 μm.

The redistribution layer 130 may include a barrier pattern 133 and a conductive pattern 135 on the barrier pattern 133. The barrier pattern 133 may be interposed between the lower insulating structure 120 and the conductive pattern 135. The barrier pattern 133 may be overlapped with the conductive pattern 135, when viewed in a plan view. In other words, the conductive pattern 135 and the barrier pattern 133 may have sidewalls that are vertically aligned with each other.

The barrier pattern 133 may be provided to substantially prevent metallic elements from being diffused from the conductive pattern 135 to the lower insulating structure 120, and for example, may be formed of or include at least one of Ti or TiN. In addition, the barrier pattern 133 may be configured to have a good wetting property with respect to the lower insulating structure 120 thereunder.

The conductive pattern 135 may include a contact portion 135a filling the contact hole 125, a conductive line portion 135b extending in the first direction D1 on the lower insulating structure 120, and a bonding pad portion 135c. The contact portion 135a, the conductive line portion 135b, and the bonding pad portion 135c may be connected to form a single body (e.g., the conductive pattern 135).

The contact portion 135a may have a second thickness T2, when measured in a direction substantially perpendicular to the top surface of the semiconductor substrate 100. In addition, the contact portion 135a in the contact hole 125 may have a fifth thickness T5, when measured in the first direction D1 or the second direction D2. Here, the second thickness T2 may be greater than the fifth thickness T5. For example, the second thickness T2 may range from about 1 μm to about 8 μm. The contact portion 135a filling the contact hole 125 may be provided to define a dent 137.

The conductive line portion 135b may be positioned between the contact portion 135a and the bonding pad portion 135c. Similar to the redistribution layers 130 previously described with reference to FIG. 2, the conductive line portion 135b may be a line-shaped structure extending in the first direction D1. The conductive line portion 135b may be provided to allow the bonding pad portion 135c on the first peripheral area PA1 to be electrically connected to the contact portion 135a on the center area CA.

The conductive pattern 135 may include a metallic material, on which a deposition and patterning process can be effectively performed. As an example, the conductive pattern 135 may be formed of or include aluminum (Al).

An upper insulating structure 140 may be provided on the redistribution layer 130 and the lower insulating structure 120. The upper insulating structure 140 may include an upper insulating layer 140a and a polymer layer 140b, which may be stacked, for example sequentially stacked on the semiconductor substrate 100. The upper insulating layer 140a may be provided to directly cover the redistribution layer 130. For example, the upper insulating layer 140a may directly cover top and side surfaces of the conductive pattern 135 and a side surface of the barrier pattern 133. As shown in FIG. 4B, the upper insulating layer 140a may directly cover the recess region RC defined by the third lower insulating layer 120c. in other words, the upper insulating layer 140a may directly cover the sidewall SW and the bottom surface BT of the recess region RC.

The polymer layer 140b may be spaced apart from the redistribution layer 130 with the upper insulating layer 140a interposed therebetween. The upper insulating structure 140 may be provided to protect the redistribution layer 130 against external environment and to substantially prevent a short circuit from being formed between the redistribution layers 130.

A first opening 145 may be provided to penetrate the first upper insulating structure 140 and to expose the bonding pad portion 135c. For example, as shown in FIG. 2, a plurality of first openings 145 may be provided on the first and second peripheral areas PA1 and PA2 to expose the bonding pad portions 135c, respectively.

The first opening 145 may have the third width W3 in the first direction D1. The third width W3 may be greater than the fourth width W4. In some example embodiments, the third width W3 may be given to allow the wire bonding process to be more easily performed on the bonding pad portion 135c. For example, the third width W3 may range from about 100 μm to 300 about μm.

In some example embodiments, the upper insulating layer 140a may include a silicon-containing inorganic insulating layer (e.g., a silicon nitride layer, a silicon oxide layer, or a silicon oxynitride layer). By contrast, the polymer layer 140b may be formed of or include an organic insulating layer (e.g., at least one of polyimide, fluoro carbon, resin, or synthetic rubber. The upper insulating layer 140a may have a third thickness T3, and the polymer layer 140b may have a fourth thickness T4. Here, the fourth thickness T4 may be greater than the third thickness T3. As an example, the third thickness 13 may range from about 0.1 μm to 3 about μm, and the fourth thickness T4 may range from about 0.3 μm to 6 about μm.

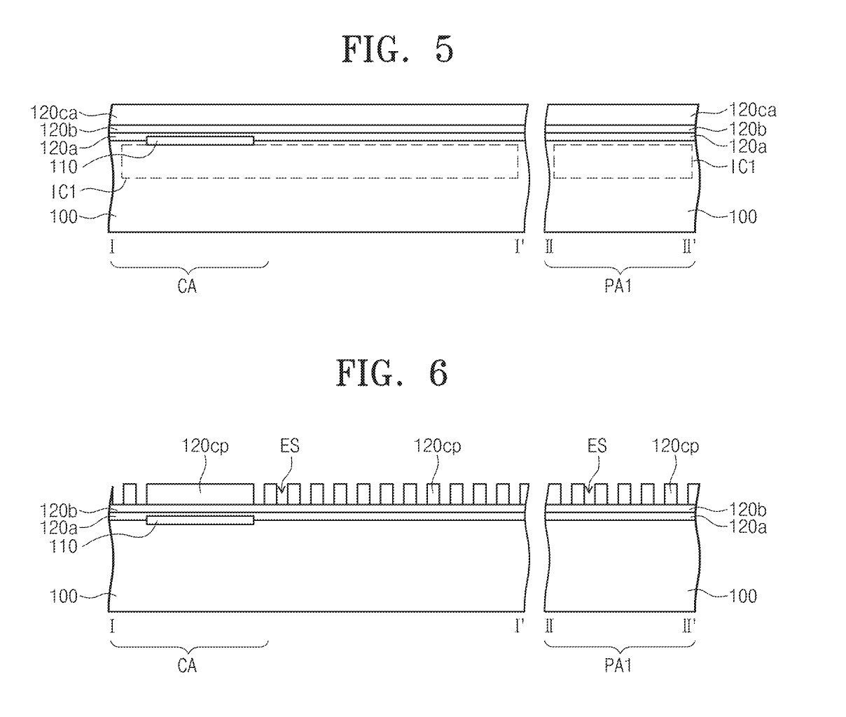

FIGS. 5 through 11 are sectional views taken along lines I-I′ and II-II′ of FIG. 2. to illustrate a method of fabricating a first semiconductor chip, according to some example embodiments of the inventive concepts.

Referring to FIGS. 2 and 5, a first integrated circuit IC1 may be formed on a semiconductor substrate 100. The formation of the first integrated circuit IC1 may include forming a plurality of transistors TR, a plurality of metal layers M1-M3, and a plurality of vias V1-V3 and may be performed using the same method as described with reference to FIG. 4A.

Pads 110 may be formed on the center area CA of the semiconductor substrate 100. The pads 110 may be electrically connected to the first integrated circuit IC1. Hereinafter, one of the pads 110 will be described, for concise description.

Lower insulating layers 120a, 120b, and 120ca may be formed to cover the pad 110. For example, the formation of the lower insulating layers 120a, 120b, and 120ca may include forming, for example sequentially forming a first lower insulating layer 120a, a second lower insulating layer 120b, and a preliminary lower insulating layer 120ca on the top surface of the semiconductor substrate 100. Each of or at least one of, the first and second lower insulating layers 120a and 120b and the preliminary lower insulating layer 120ca may be formed via an atomic layer deposition (ALD) process or a chemical vapor deposition (CVD) process. As an example, the first lower insulating layer 120a and the preliminary lower insulating layer 120ca may be formed of or include a silicon oxide layer, and the second lower insulating layer 120b may be formed of or include a silicon nitride layer.

Referring to FIGS. 2 and 6, the preliminary lower insulating layer 120ca may be patterned to form a plurality of lower insulating patterns 120cp. Here, the lower insulating patterns 120cp may be formed to define empty spaces ES therebetween.

Although not shown, each of the empty spaces ES may be shaped like a circle, rectangle, or square, when viewed in a plan view. The empty spaces ES may be arranged in first and second directions D1 and D2. Alternatively, each of the empty spaces ES may have a line-shaped gap extending in the second direction D2, but the inventive concepts may not be limited thereto.

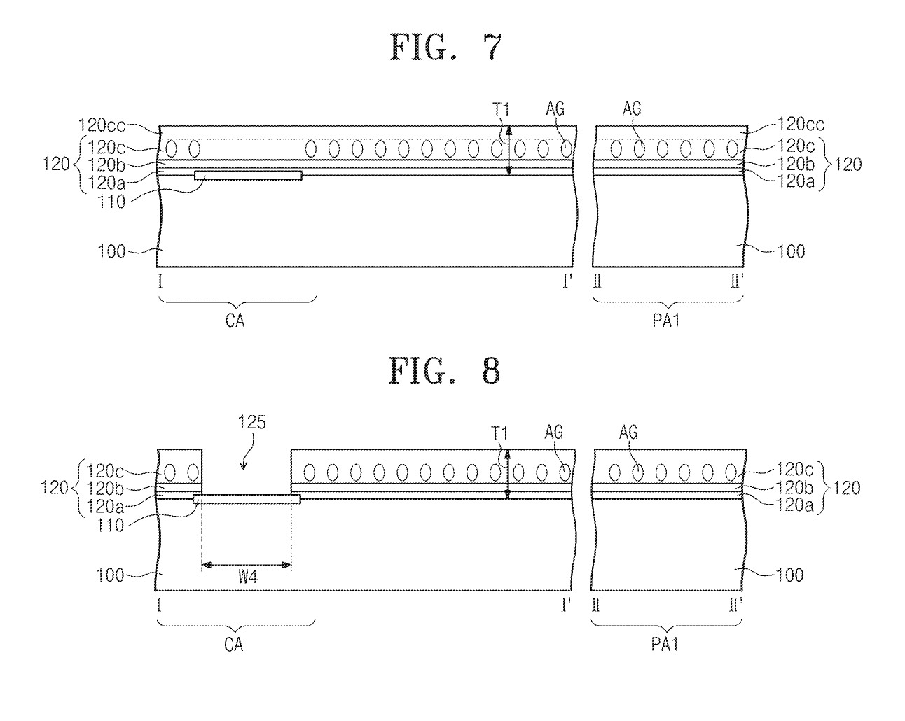

Referring to FIGS. 2 and 7, an additional insulating layer 120cc may be deposited on the lower insulating patterns 120cp to form a third lower insulating layer 120c with a plurality of air gaps AG. For example, the additional insulating layer 120cc may be formed via a deposition method with a poor step coverage property (e.g., a physical vapor deposition (PVD) process or a chemical vapor deposition (CVD) process) Accordingly, portions of the empty spaces ES may not be filled with the additional insulating layer 120cc, thereby serving as the air gaps AG.

As an example, the additional insulating layer 120cc may be formed of or include the same material as the lower insulating patterns 120cp. Accordingly, the additional insulating layer 120cc and the lower insulating patterns 120cp may constitute a single insulating layer (i.e., the third lower insulating layer 120c). In some example embodiments, the first to third lower insulating layers 120a, 120b, and 120c may constitute the lower insulating structure 120.

Referring to FIGS. 2 and 8, the lower insulating structure 120 may be patterned to form a contact hole 125 exposing the pad 110. The patterning of the lower insulating structure 120 may include forming a first photoresist pattern (not shown) with an opening vertically overlapping the pad 110 and etching the lower insulating structure 120 using the first photoresist pattern as an etch mask. The contact hole 125 may be formed to have a fourth width W4. For example, the fourth width W4 may range from about 5 μm to about 50 μm.

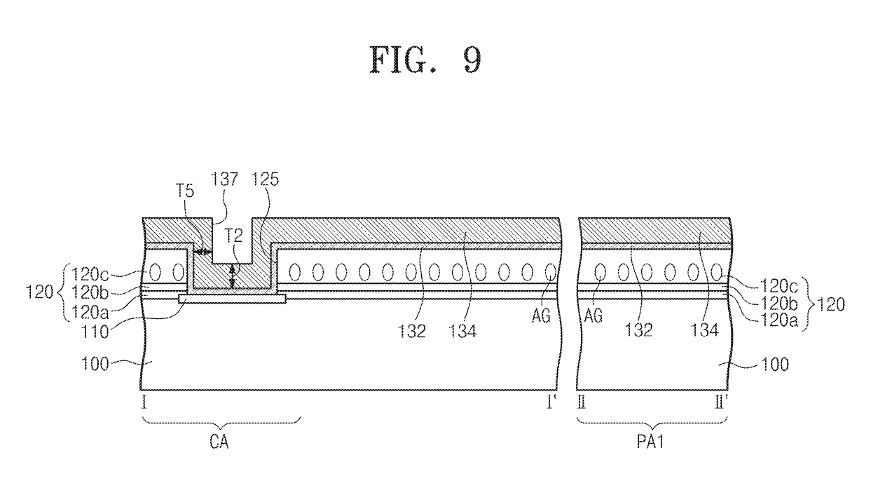

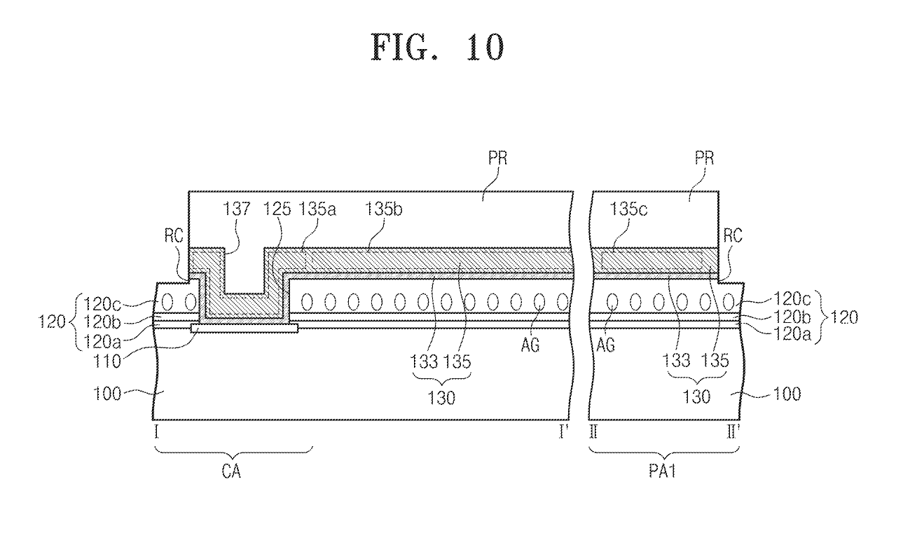

Referring to FIGS. 2 and 9, a barrier layer 132 and a conductive layer 134 may be formed, for example sequentially formed on the resulting structure with the lower insulating structure 120. Each of the barrier layer 132 and the conductive layer 134 may be formed to fill at least a portion of the contact hole 125. In some example embodiments, the barrier layer 132 may be formed to directly cover the pad 110, and the conductive layer 134 may be formed to at least partially, and not wholly, fill the contact hole 125, thereby defining a dent 137.

The barrier layer 132 and the conductive layer 134 may be formed using a physical vapor deposition (PVD) process. Here, the conductive layer 134 in the contact hole 125 may be formed to have a second thickness T2, when measured in a direction substantially perpendicular to the top surface of the semiconductor substrate 100. The conductive layer 134 in the contact hole 125 may have a fifth thickness T5, when measured in the first direction D1 or the second direction 1)2. Since the conductive layer 134 is formed by a deposition method with a poor step coverage property (e.g., PVD process), the second thickness T2 may be greater than the fifth thickness T5.

In some example embodiments, the barrier layer 132 may be formed of or include at least one of Ti or TiN. The conductive layer 134 may be formed of or include a metallic material (e.g., containing aluminum (Al)).

Referring to FIGS. 2 and 10, a second photoresist pattern PR may be formed on the conductive layer 134. In some example embodiments, a plurality of second photoresist patterns PR may be formed to define positions and shapes of the redistribution layers 130 described with reference to FIGS. 2 and 3.

The conductive layer 134 and the barrier layer 132 may be etched, for example sequentially etched using the second photoresist pattern PR as an etch mask to form the redistribution layer 130. The etching process of the conductive layer 134 and the barrier layer 132 may be performed using a dry etching process. As an example, an etching gas containing BCl₃ and/or SF₆ may be used for the dry etching process, but the inventive concepts may not be limited thereto. The redistribution layer 130 may include a barrier pattern 133 and a conductive pattern 135 on the barrier pattern 133. The conductive pattern 135 may include a contact portion 135a, a conductive line portion 135b, and a bonding pad portion 135c.

In the case where the second photoresist pattern PR is used as a common mask for forming the conductive pattern 135 and the barrier pattern 133, the conductive pattern 135 and the barrier pattern 133 may overlap each other, when viewed in a plan view. Accordingly, the conductive pattern 135 and the barrier pattern 133 may be formed to have sidewalls aligned with each other in plan view.

An upper portion of the lower insulating structure 120 may be etched during the process of etching the conductive layer 134 and the barrier layer 132. For example, during the etching process, the conductive layer 134 and the barrier layer 132 exposed by the second photoresist pattern PR. may be removed, and then, a portion of the third lower insulating layer 120c thereunder may be at least partially etched. As a result, during the process of etching the redistribution layer 130, a recess region RC may be formed in the third lower insulating layer 120c. Here, the recess region RC may be formed to have a bottom surface that is lower than the top surface of the third lower insulating layer 120c provided under the redistribution layer 130.

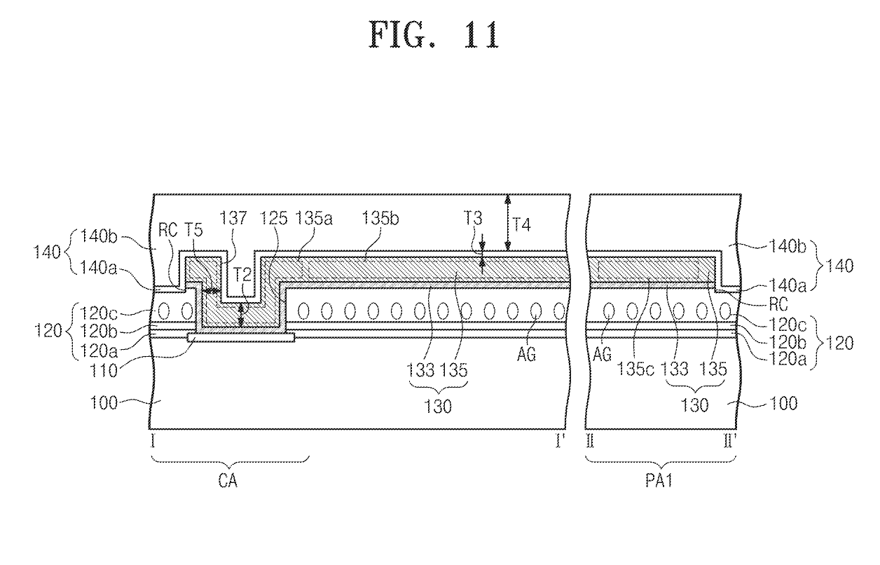

Referring to FIGS. 2 and 11, a remaining portion of the second photoresist pattern PR may be selectively removed, Thereafter, an upper insulating structure 140 may be formed on the redistribution layer 130 and the lower insulating structure 120.

For example, the formation of the upper insulating structure 140 may include forming, for example sequentially forming an upper insulating layer 140a and a polymer layer 140b on the semiconductor substrate 100. The upper insulating layer 140a may be formed via, for example, an atomic layer deposition (ALD) process or a chemical vapor deposition (CVD) process. The polymer layer 140b may be formed by coating a polymer material (e.g., at least one of polyimide, fluoro carbon, resin, or synthetic rubber) or a precursor thereof on the upper insulating layer 140a. The upper insulating layer 140a may be formed to have a third thickness 13, and the polymer layer 140b may be formed to have a fourth thickness T4. Here, the fourth thickness T4 may be greater than the third thickness T3.

Referring to FIGS. 2 and 3, the upper insulating structure 140 may be patterned to form a first opening 145 exposing the bonding pad portion 135c. The patterning of the upper insulating structure 140 may include forming a third photoresist pattern (not shown) and etching the upper insulating structure 140 using the third photoresist pattern as an etch mask, where the third photoresist pattern is formed to define an opening overlapped with the bonding pad portion 135c. The first opening 145 may be formed to have a third width W3. For example, the third width W3 may range from about 100 μm to about 300 μm. In a subsequent package process, a wire bonding process may be performed on the bonding pad portion 135c exposed by the first opening 145.

According to some example embodiments of the inventive concepts, the redistribution layer 130 may be formed of or include a less expensive metal (e.g., aluminum) than gold or copper, and thus, it is possible to reduce production cost in a process of fabricating a semiconductor chip. In addition, the redistribution layer 130 may be formed by a deposition and a patterning process instead of by a plating process, and thus, this may make it possible to use the existing metal patterning system for the process of forming the redistribution layer 130. Accordingly, it is possible to improve process efficiency in the fabrication process.

Furthermore, in a fabrication method according to some example embodiments of the inventive concepts, a plurality of air gaps AG may be formed in the lower insulating structure. The presence of the air gaps AG may reduce an effective dielectric constant of the lower insulating structure 120.

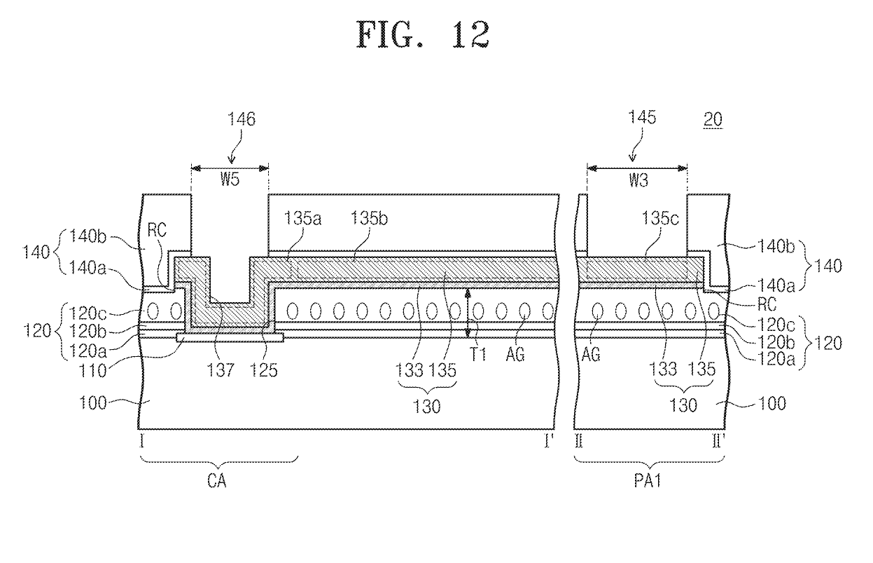

FIG. 12 is a sectional view of sections, which are respectively taken along lines I-I′ and II-II′ of FIG. 2, and illustrates a first semiconductor chip according to some example embodiments of the inventive concepts. In the following description, an element of the first semiconductor chip previously described with reference to FIGS. 2 to 4B may be identified by a similar or identical reference number without repeating an overlapping description thereof, for the sake of brevity.

Referring to FIGS. 2 and 12, a second opening 146 may be provided to penetrate the upper insulating structure 140 and expose the contact portion 135a. The second opening 146 may have a fifth width W5. In some example embodiments, the fifth width W5 may range from about 10 μm to about 100 μm.

Although not shown, an additional outer terminal may be coupled to the contact portion 135a through the second opening 146. Accordingly, this structure of the contact portion 135a, in conjunction with the bonding pad portion 135c exposed by the first opening 145, may make it possible to increase a degree of freedom in establishing a routing path with an external controller (not shown).

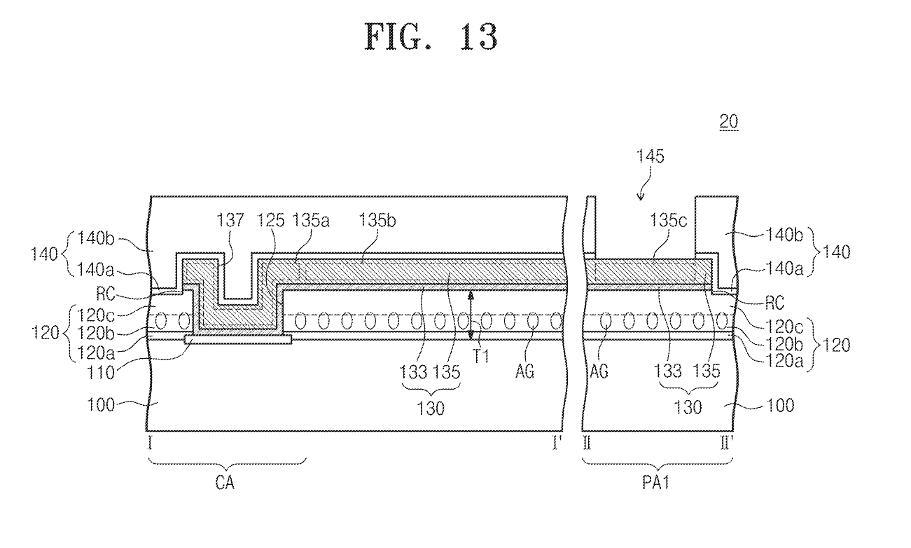

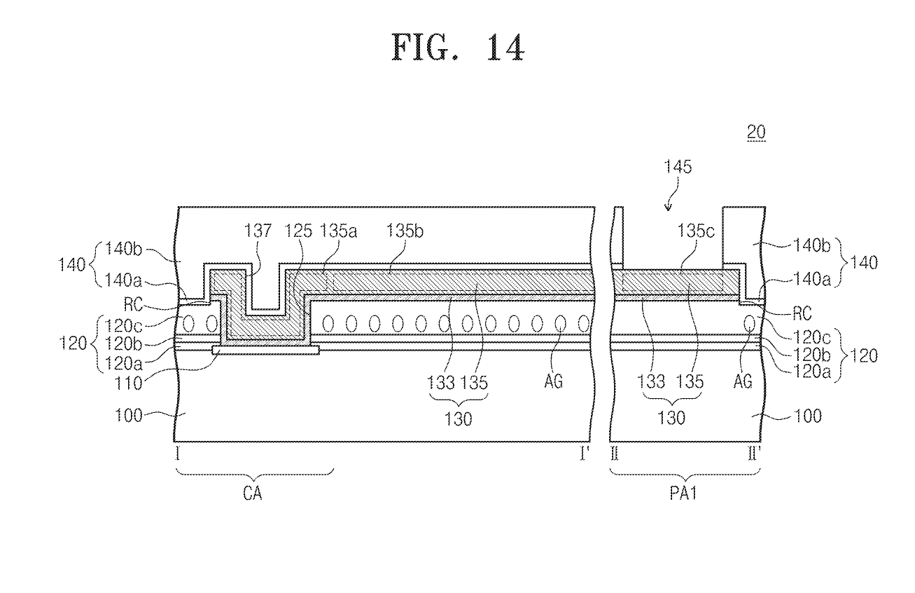

FIG. 13 is a sectional view of sections, which are respectively taken along lines 14′ and of FIG. 2, and illustrates a first semiconductor chip according to some example embodiments of the inventive concepts. In the following description, an element of the first semiconductor chip previously described with reference to FIGS. 2 to 4B may be identified by a similar or identical reference number without repeating an overlapping description thereof, for the sake of brevity.

Referring to FIGS. 2. and 13, a plurality of air gaps AG may be interposed between the second lower insulating layer 120b and the third lower insulating layer 120c. The second lower insulating layer 120b and the third lower insulating layer 120c may include materials that are different from each other; for example, the second lower insulating layer 120b may be formed of or include a silicon nitride layer, and the third lower insulating layer 120c may be formed of or include a silicon oxide layer.

As an example, a silicon oxide layer as the additional insulating layer 120cc may be deposited during the process of forming the air gaps AG described with reference to FIG. 7. In this case, the second lower insulating layer 1120b may be used to form the lower insulating patterns 120cp. The additional insulating layer 120cc may constitute the third lower insulating layer 120c, and thus, the air gaps AG may be interposed between layers made of or including different materials.

FIG. 14 is a sectional view of cross-sections respectively taken along lines I-I′ and of FIG. 2, and illustrates a first semiconductor chip according to some example embodiments of the inventive concepts. In the following description, an element of the first semiconductor chip previously described with reference to FIGS. 2 to 4B may be identified by a similar or identical reference number without repeating an overlapping description thereof, for the sake of brevity.

Referring to FIGS. 2 and 14, when viewed in a plan view, the air gaps AG may be provided spaced apart from the bonding pad portion. In other words, the air gaps AG may not be overlapped with the bonding pad portion, when viewed in a plan view. The air gaps AG may reduce an effective dielectric constant of the lower insulating structure 120, but it may lead to deterioration in structural stability of the lower insulating structure 120.

As shown in FIG. 1, an outer terminal (e.g., the wire 8) may be connected to the bonding pad portion, and in this case, the outer terminal may exert a mechanical stress to an underlying structure. In some example embodiments, the air gaps AG may not be formed below the bonding pad portion, and thus, the lower insulating structure 120 supporting the bonding pad portion may have an improved structural stability.

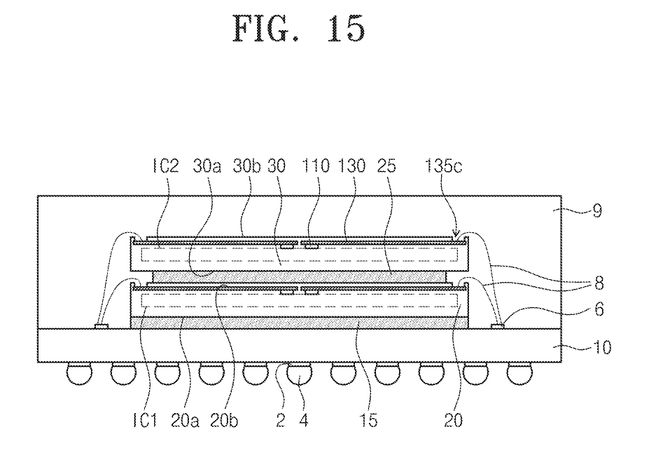

FIG. 15 is a sectional view illustrating a semiconductor package according to some example embodiments of the inventive concepts. In the following description, an element of the semiconductor package previously described with reference to FIGS. 1 and 2 may be identified by a similar or identical reference number without repeating an overlapping description thereof, for the sake of brevity.

Referring to FIG. 15, the first semiconductor chip 20 may be mounted on the package substrate 10, and a second semiconductor chip 30 may be mounted on the first semiconductor chip 20. The second semiconductor chip 30 may have a third surface 30a facing the first semiconductor chip 20 and a fourth surface 30b opposite to the third surface 30a.

The second semiconductor chip 30 may be a chip that is the same as or similar to the first semiconductor chip 20. For example, the second semiconductor chip 30 may be configured to have a second integrated circuit IC2, in addition to the pads 110 and the redistribution layers 130. The redistribution layers 130 may include the bonding pad portions 135c. In some example embodiments, the second semiconductor chip 30 may be one of a number of memory chips (e.g., DRAM chips or FLASH memory chips). The second integrated circuit IC2 may include memory cells for storing data and a control and/or power circuit for controlling operations of the memory cells.

The second semiconductor chip 30 may be attached to the first semiconductor chip 20 using the second adhesive layer 25. The second adhesive layer 25 may be an insulating layer or tape (e.g., containing an epoxy or silicone-based material). The second adhesive layer 25 may have a top surface positioned at a higher level than the topmost level of the wires 8 connected to the first semiconductor chip 20.

The wires 8 may be provided to respectively connect the bonding pad portions 135c of the second semiconductor chip 30 to the second outer pads 6 of the package substrate 10. The second semiconductor chip 30 may communicate with an external controller (not shown) through the wires 8.

The mold layer 9 may be provided on the package substrate 10 to cover the first and second semiconductor chips 20 and 30 and the wires 8. The mold layer 9 may be configured to protect the first and second semiconductor chips 20 and 30 and the wires 8 against external environment.

In some example embodiments, the semiconductor package may further include at least one semiconductor chip disposed on the second semiconductor chip 30, in addition to the first and second semiconductor chips 20 and 30.

According to some example embodiments of the inventive concepts, a redistribution layer of a semiconductor chip may be formed by a deposition and patterning process, not by a plating process. This may make it possible to economically fabricate a semiconductor chip. Furthermore, by providing air gaps in a lower insulating layer, it is possible to reduce parasitic capacitance of a semiconductor chip.

While example embodiments of the inventive concepts have been particularly shown and described, it will be understood by one of ordinary skill in the art that variations in form and detail may be made therein without departing from the spirit and scope of the attached claims.

1. A semiconductor chip, comprising:
an integrated circuit on a substrate;
a pad electrically connected to the integrated circuit;
a lower insulating structure having a contact hole exposing the pad; and
a conductive pattern including a contact portion filling the contact hole, a conductive line portion on the lower insulating structure and extending in a specific direction, and a bonding pad portion, wherein,
the contact portion has a first thickness in a direction substantially perpendicular to a top surface of the substrate and a second thickness in another direction substantially parallel to the top surface of the substrate,
the first thickness is greater than the second thickness, and
the lower insulating structure includes a plurality of air gaps.

2. The semiconductor chip of claim 1, wherein
the lower insulating structure comprises a plurality of lower insulating layers stacked on the substrate.

3. The semiconductor chip of claim 2, wherein
the air gaps are provided in the uppermost layer of the lower insulating layers.

4. The semiconductor chip of claim 2, wherein
the lower insulating structure includes a first lower insulating layer and a second lower insulating layer stacked on the substrate,
the first lower insulating layer and the second lower insulating layer include inorganic materials, and the inorganic materials are different from each other, and
the air gaps are interposed between the first and second lower insulating layers.

5. The semiconductor chip of claim 1, wherein, when viewed in a plan view, the air gaps do not overlap the bonding pad portion.

6. The semiconductor chip of claim 1, wherein the lower insulating structure has a recess region formed in an upper portion thereof, and
when viewed in a plan view, the recess region does not overlap the conductive pattern.

7. The semiconductor chip of claim 6, wherein the recess region has a sidewall aligned with a sidewall of the conductive pattern, and
the recess region has a bottom surface that is lower than a top surface of the lower insulating structure provided below the conductive pattern.

8. The semiconductor chip of claim 1, wherein the contact portion fills the contact hole and defines a dent.

9. The semiconductor chip of claim 1, wherein the pad is electrically connected to the integrated circuit thereunder through at least one of a plurality of metal layers and a plurality of vias.

10. The semiconductor chip of claim 1, wherein, when viewed in a plan view, the pad is on a center area of the semiconductor chip and the bonding pad portion is provided on a peripheral area of the semiconductor chip.

11. The semiconductor chip of claim 1, further comprising an upper insulating structure having a first opening exposing the bonding pad portion,
wherein the upper insulating structure includes,
an upper insulating layer covering the lower insulating structure and the conductive pattern; and
a polymer layer on the upper insulating layer.

12-16. (canceled)

17. The semiconductor chip of claim 1, wherein the conductive pattern comprises an aluminum-containing material.

18. (canceled)

19. A semiconductor chip, comprising:
an integrated circuit on a substrate;
a pad electrically connected to the integrated circuit;
a lower insulating structure having a contact hole exposing the pad; and
a conductive pattern including a contact portion filling the contact hole, a conductive line portion provided on the lower insulating structure and extending in a specific direction, and a bonding pad portion,
wherein the lower insulating structure includes a first region and a second region, a top surface thereof is lower than a top surface of the first region,
the first region overlaps the conductive pattern in a plan view,
the second region is exposed by the conductive pattern, and
the lower insulating structure includes a plurality of air gaps provided therein.

20. The semiconductor chip of claim 19, further comprising:
an upper insulating structure having an opening exposing the bonding pad portion,
wherein the upper insulating structure includes,
an upper insulating layer covering the lower insulating structure and the conductive pattern; and
a polymer layer on the upper insulating layer.

21. The semiconductor chip of claim 20, wherein the upper insulating layer directly covers a top surface of the second region.

22. The semiconductor chip of claim 19, further comprising:
a barrier pattern between the lower insulating structure and the conductive pattern, wherein
the conductive pattern includes an aluminum-containing material, and
the barrier pattern includes Ti, TiN, or any combination thereof.

23-33. (canceled)

34. A semiconductor chip, comprising:
a pad on a substrate, the pad being electrically connected to a circuit;
an insulating structure on the pad and the substrate, the insulating structure including a contact hole;
a redistribution layer on the insulating structure and at least partially filling the contact hole, the redistribution layer including a barrier pattern and a conductive pattern having a contact portion in the contact hole, the contact portion having a first thickness in a first direction greater than a second thickness in a second direction, and
the insulating structure including a plurality of air gaps.

35. The semiconductor chip of claim 34, wherein
the redistribution layer comprises an aluminum-containing material.

36. The semiconductor chip of claim 36, wherein
the conductive pattern further includes a conductive line portion on the insulating structure, and a bonding pad portion.

37. The semiconductor chip of claim 36, wherein
the first direction is substantially perpendicular to a surface of the substrate and the second direction is substantially parallel to the surface of the substrate.
